(19) United States
(12) Patent Application Publication
(10) Pub. No.: US 2008/0087938 A1
(43) Pub. Date: Apr. 17, 2008

(54) Mask ROM, mask ROM embedded EEPROM and method of fabricating the same

(76) Inventors: Hee-seog Jeon, Suwon-si (KR); Jeong-uk Han, Suwon-si (KR)

Correspondence Address: HARNESS, DICKEY & PIERCE, P.L.C., P.O. BOX 8910, RESTON, VA, 20195, US

(21) Appl. No.: 11/905,629

(22) Filed: Oct. 3, 2007

(30) Foreign Application Priority Data
Oct. 3, 2006 (KR) 10-2006-97469

(51) Int. Cl. H01L 27/115; H01L 27/112; H01L 21/8247

(52) U.S. Cl. 257/316; 257/390; 438/266; 257/E27.102; 257/E27.103; 257/E21.645

(57) ABSTRACT

Example embodiments are directed to a mask ROM, a mask ROM embedded EEPROM and a method of fabricating the same. The mask ROM may include a select gate pattern and a memory gate pattern disposed between a source region and a drain region at each of the on-cell and the off-cell. The on-cell may include a cell diffusion region between the select gate pattern and the memory gate pattern.

### PRIORITY STATEMENT

This application claims priority under 35 U.S.C. § 119 to Korean Patent Application No. 10-2006-97469, filed on Oct. 3, 2006, in the Korean Intellectual Property Office, the entire contents of which are incorporated herein by reference.

### BACKGROUND

1. Field

Example embodiments are directed towards a semiconductor device and a method of fabricating the same, for example, to a mask ROM, a mask ROM embedded EEPROM, and a method of fabricating the same.

2. Description of the Related Art

A typical memory embedded logic semiconductor device may utilize EEPROM and mask ROM as a memory region. The mask ROM may integrate higher capacity data. Since the size of the mask ROM cell is smaller than the size of a typical 2-transistor EEPROM cell, the mask ROM cell and 2-transistor EEPROM cell may be used together as a memory region for higher integration.

Since mask ROM requires a peripheral region, the size of a chip may be larger and an additional mask may be required for mask ROM coating. Recently, sizes of 2-transistor EEPROM cell have become smaller.

Additionally, in semiconductor devices that only use EEPROM as a memory region, a part of EEPROM may be used as fixed data. In this example, it may take a longer time to program data and test products before shipping.

### SUMMARY

Example embodiments provide a mask ROM in which data may be written without a mask for coating, EEPROM in which the mask ROM may be embedded, and a method of fabricating the same.

For example, the mask ROM may include an on-cell and an off-cell with a select transistor and a memory transistor.

The on-cell and the off-cell may include a select gate pattern and a memory gate pattern disposed between a source region and a drain region. The on-cell may include a cell diffusion region between the select gate pattern and the memory gate pattern, and the off-cell may not include the cell diffusion region between the select gate pattern and the memory gate pattern.

The cell diffusion region may connect the select transistor and the memory transistor in series at the on-cell in order to provide a current path for recording data 1. Since the cell diffusion region is not formed on the off-cell, the current path between the select transistor and the memory transistor may be cut off so that data 0 is recorded.

The mask ROM may be embedded in EEPROM. A mask ROM embedded EEPROMs may include an EEPROM cell and a mask ROM cell. The EEPROM cell may include a first source region, a first drain region, a first select gate pattern and a first memory gate pattern disposed between the first source region and the first drain region, and a first cell diffusion region disposed between the first select gate pattern and the first memory gate pattern. The mask ROM cell may include a second source region, a second drain region, a second select gate pattern and a second memory gate pattern disposed between the second source region and the second drain region. The mask ROM cell may include an on-cell and an off-cell. The on-cell may include a second cell diffusion region between the second select gate pattern and the second memory gate pattern, and the off-cell may not include a cell diffusion region between the second select gate pattern and the second memory gate pattern.

Example embodiments show methods of fabricating a mask ROM may include providing a semiconductor substrate including an off-cell region and an on-cell region on, forming a select gate pattern and a memory gate pattern on the off-cell region and the on-cell region, forming a mask pattern to cover the semiconductor substrate between the select gate pattern and the memory gate patterns in the off-cell region. Example embodiments may also include forming a source region disposed in the semiconductor substrate adjacent to the select gate pattern, a cell diffusion layer disposed in the semiconductor substrate between the select gate pattern and the memory gate pattern of the on-cell region, and a drain region disposed in the semiconductor substrate adjacent to the memory gate pattern by implanting impurity on the off-cell region and the on-cell region using the mask pattern as an ion implantation mask.

Methods of fabricating a mask ROM may include providing a semiconductor substrate including an EEPROM region, an off-cell region, and an on-cell region, forming a select gate pattern and a memory gate pattern on the EEPROM region, the off-cell region, and the on-cell region, forming a mask pattern to cover the semiconductor substrate between the select gate pattern and the memory gate pattern of the off-cell region. Example embodiments may also include forming a source region disposed in the semiconductor substrate adjacent to the select gate pattern, a cell diffusion layer disposed in the semiconductor substrate between the select gate pattern and the memory gate pattern of the EEPROM region and the on-cell region, and a drain region disposed in the semiconductor substrate adjacent to the memory gate pattern by implanting impurity on the EEPROM region, the off-cell region, and the on-cell region using the mask pattern as an ion implantation mask.

### BRIEF DESCRIPTION OF THE DRAWINGS

The above and other features and advantages of example embodiments will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIG. 1 is an equivalent circuit of mask ROM and mask ROM embedded EEPROM according to example embodiments.

FIG. 2 is a cross sectional view of mask ROM and mask ROM embedded EEPROM according to example embodiments.

FIGS. 3 through 5 are cross sectional views illustrating a method of fabricating mask ROM and mask ROM embedded EEPROM according to example embodiments.

FIGS. 6 through 8 are cross sectional views illustrating a method of fabricating mask ROM and mask ROM embedded EEPROM according to example embodiments.

### DETAILED DESCRIPTION OF PREFERRED EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Example embodiments disclose that the mask ROM and an EEPROM cell may share a word line or a bit line. For example, the memory region may be divided into a mask ROM region and an EEPROM region along a word line direction such that 0 to n^{th} bit lines are used as the mask ROM region and n+1 to m^{th} bit lines are used as the EEPROM region.

The memory region may be divided into a mask ROM region and an EEPROM region along a bit line direction such that 0 to n^{th} word lines are used as the mask ROM region and n+1 to m^{th} word lines are used as the EEPROM region.

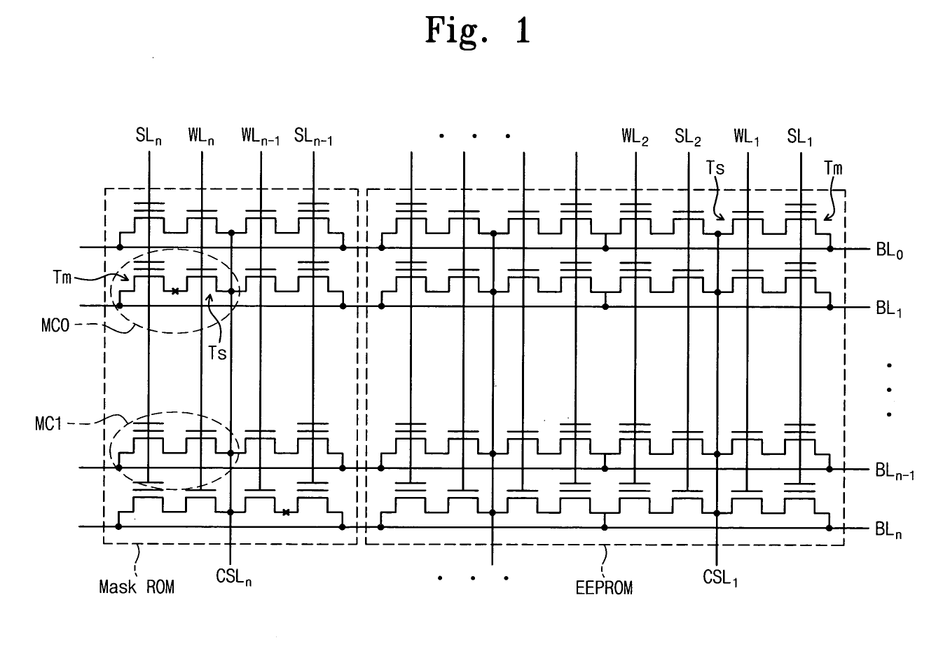

FIG. 1 is an equivalent circuit of mask ROM and mask ROM embedded EEPROM according to example embodiments.

Referring to FIG. 1, the mask ROM may have a structure similar to that of a typical 2-transistor EEPROM, and a cell array of a mask ROM embedded EEPROM may have a structure similar to that of a typical 2-transistor EEPROM.

As illustrated in FIG. 1, a mask ROM region Mask ROM may include mask ROM cells MC0 and MC1 with select transistors Ts and memory transistors Tm, which may be connected in series. The mask ROM cell may be divided into an on-cell MC1 and an off-cell MC0, which may be selectively formed according to coded data.

In the on-cell MC1, the select transistor Ts and the memory transistor Tm may be connected in series to provide a current path. In the off-cell MC0, the select transistor Ts and the memory transistor Tm may be off to break the current path.

The mask ROM region Mask ROM may include a NOR array. For example, a plurality of mask ROM cells may be disposed in a row direction and a column direction in the mask ROM region, and a word line WLn to which gate electrodes of the select transistors Ts may be connected and a sensing line SLn to which gate electrodes of the memory transistors Tm may be connected in a direction parallel to the word line WLn are disposed.

The mask ROM cells may be symmetrically disposed such that adjacent mask ROM cells may share a source region or a drain region. Source regions of the mask ROM cells may be connected to a common source line CSLn parallel to the word line WLn and the sensing line SLn. Drain regions of the mask ROM cells may be connected to a bit line BLn intersecting the word line WLn and the sensing line SLn.

The mask ROM region and the EEPROM region may be divided in a bit line direction. For example, the bit line BLn may be shared in the mask ROM region and the EEPROM region. In alternative example embodiments, if the mask ROM region and the EEPROM region are divided in a word line direction, the word line WLn may be shared in the mask ROM region and the EEPROM region.

The EEPROM region may include a 2-transistor EEPROM cell. The 2-transistor EEPROM cell may include a select transistor Ts and a memory transistor Tm, which may be connected in series. For example, the EEPROM cell may have a structure identical to that of the on-cell.

The EEPROM region also includes a NOR array. The EEPROM cells may be disposed in a row direction and a column direction, and a word line WLn to which the gate electrodes of the select transistors Ts are connected and the sensing line SLn to which the gate electrodes of the memory transistors Tm are connected in parallel to the word line WLn may be disposed.

The EEPROM cell may be symmetrically disposed such that the adjacent mask ROM cells share the source region and the drain region. The source regions of the mask ROM cells may be connected to the common source line CSLn parallel to the word line WLn and the sensing line SLn. The drain regions of the mask ROM cells may be connected to the bit line BLn intersecting the word line WLn and the sensing line SLn.

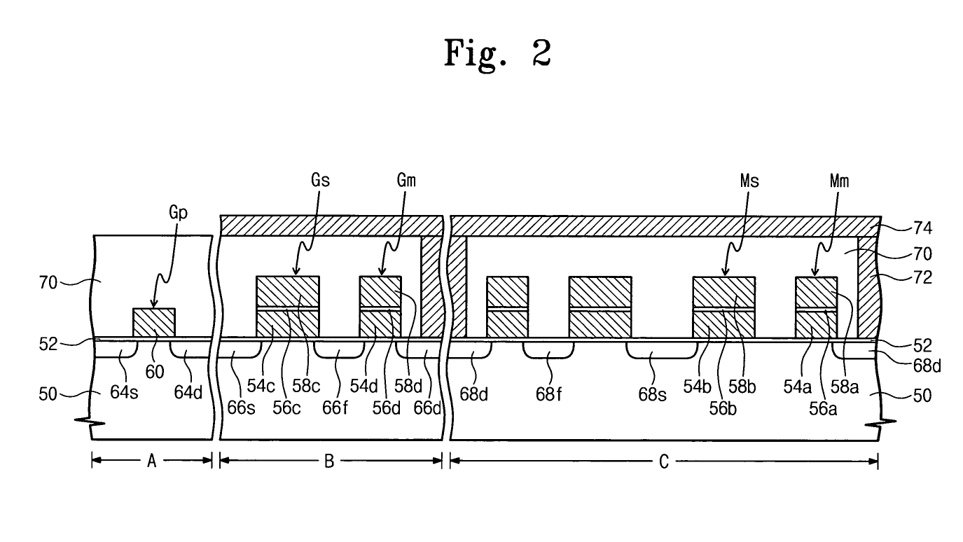

FIG. 2 is a cross-sectional view illustrating example embodiments of a mask ROM and mask ROM embedded EEPROM.

Referring to FIG. 2, a peripheral circuit region A, an EEPROM region B, and a mask ROM region C may be defined on a semiconductor substrate 50, and also an active region may be defined on the semiconductor substrate 50. A gate insulating layer 52 may be formed on the active region. A peripheral circuit transistor may be formed on the peripheral circuit region A, and an EEPROM cell may be formed on the EEPROM region B, and a mask ROM on-cell and a mask ROM off-cell may be formed on the mask ROM region C.

A gate pattern Gp of the peripheral circuit transistor may be formed on the peripheral circuit region A, and a peripheral circuit source region 64s and a peripheral circuit drain region 64d may be formed in the semiconductor substrate 50 at both sides of the gate pattern Gp of the peripheral circuit transistor.

The EEPROM cell may include a select transistor and a memory transistor, which may be connected in series. A select gate pattern Gs of the select transistor and a memory gate pattern Gm of the memory transistor may be spaced apart. A cell diffusion region 66f may be formed in the active region between the select gate pattern Gs and the memory gate pattern Gm. A cell source region 66s and a cell drain region 66d may be formed in the EEPROM cell. The cell source region 66s may be adjacent to the select gate pattern Gs, and the cell drain region 66d may be adjacent to the memory gate pattern Gm. The select gate pattern Gs may have a structure in which a first gate pattern 54c, a dielectric layer 56c, and a second gate pattern 58c are stacked on the gate insulating layer 52, and the first gate pattern 54c and the second gate pattern 58c may be electrically connected (not shown). The memory gate pattern Gm may have a structure in which a floating gate 54d, an intergate dielectric layer 56d, and a control gate electrode 58d are stacked on the gate insulating layer 52.

The mask ROM cell may have a structure similar to that of the EEPROM cell. For example, the on-cell of the mask ROM may have the same structure as the EEPROM cell, and the off-cell of the mask ROM may have the same structure as EEPROM cell but without the cell active region. For example, the on-cell may include a select gate pattern Ms and a memory gate pattern Mm spaced a given distance apart, and a cell diffusion region 68f may be formed in the semiconductor substrate 50 between the select gate pattern Ms and the memory gate pattern Mm. A source region 68s of the mask ROM may be formed in the semiconductor substrate 50 adjacent to the select gate pattern Ms, and a drain region 68d of the mask ROM may be formed in the semiconductor substrate 50 adjacent to the memory gate pattern Mm. In the mask ROM region, the memory gate pattern Mm may have a structure in which a floating gate 54a, an intergate dielectric layer 56a, and a control gate electrode 58d are stacked on the gate insulating layer 52. The select gate pattern Ms may have a structure in which a first gate pattern 54b, a dielectric layer 56b, and a second gate pattern 58b are stacked on the gate insulating layer 52. The first gate pattern 54b and the second gate pattern 58b may be electrically connected (not shown).

The peripheral circuit region A, the EEPROM region B, and the mask ROM region C may be covered with the interlayer dielectric layer 70, and a bit line 74 may be formed on the interlayer dielectric layer 70. As illustrated, the cell drain region 66d of the EEPROM region B and the drain region 68d of the mask ROM region B may be connected to the bit line 74. In a further example, when the EEPROM region B and the mask ROM C are separated in the word line direction, the select gate patterns Gs and Ms may be connected to each other, and the memory gate patterns Gm and Mm may be connected to each other.

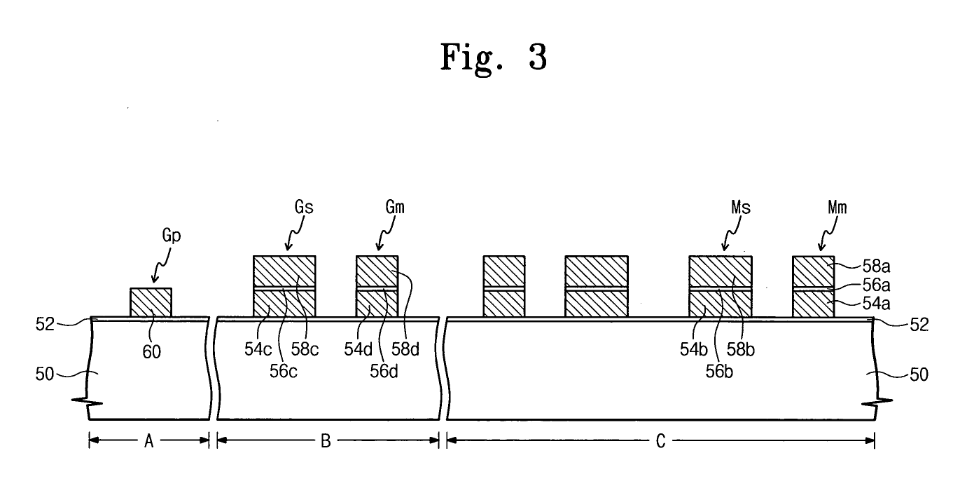

FIGS. 3 through 5 are cross-sectional views illustrating example embodiments of a method of fabricating mask ROM and mask ROM embedded EEPROM.

Referring to FIG. 3, a peripheral circuit region A, an EEPROM region B, and a mask ROM region C may be defined on a semiconductor substrate 50, and an active region may be formed. A gate insulating layer 52 may be formed on the active regions. The gate insulating layer 52 may have different thickness at each region.

A gate pattern Gp of the peripheral circuit transistor, a gate pattern Gs of a select transistor, and a gate pattern Gm of a memory transistor may be formed on the gate insulating layer 52. The gate pattern Gp of the peripheral circuit transistor may be formed on the peripheral circuit region A. The select gate pattern Gs of the select transistor and the memory gate pattern Gm of the memory transistors may be spaced apart from each other, and may be formed on the EEPROM region B. The select gate pattern Gs may have a structure in which a first gate pattern 54c, a dielectric layer 56c, and a second gate pattern 58c are stacked on the gate insulating layer 52. A portion of the dielectric layer 56c may be removed so that the first gate pattern 54c and the second gate pattern 58c may be electrically connected to each other (not shown). The memory gate pattern Gm may have a structure in which a floating gate 54d, an intergate dielectric layer 56d, and a control gate electrode 58d are stacked on the gate insulating layer 52. A select gate pattern Ms and a memory gate pattern Mm having a structure similar to that of the EEPROM cell may be disposed on the mask ROM region C.

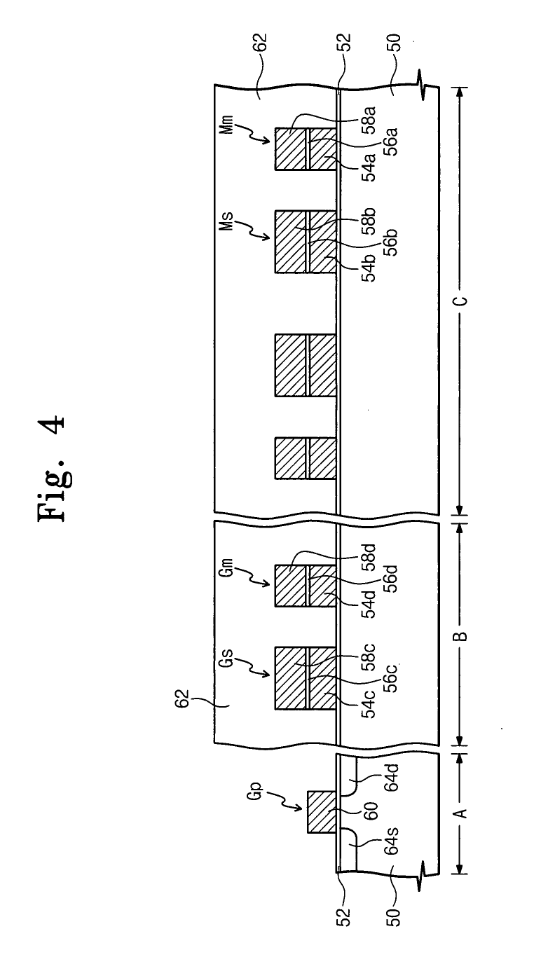

Referring to FIG. 4, a first mask pattern 62 may be formed to cover the EEPROM region B and the mask ROM region C, and a peripheral circuit source region 64s and a peripheral circuit drain region 64d may be formed on the peripheral circuit region A by using the first mask pattern 62 and the gate pattern Gp of the peripheral circuit transistor as an ion implantation mask.

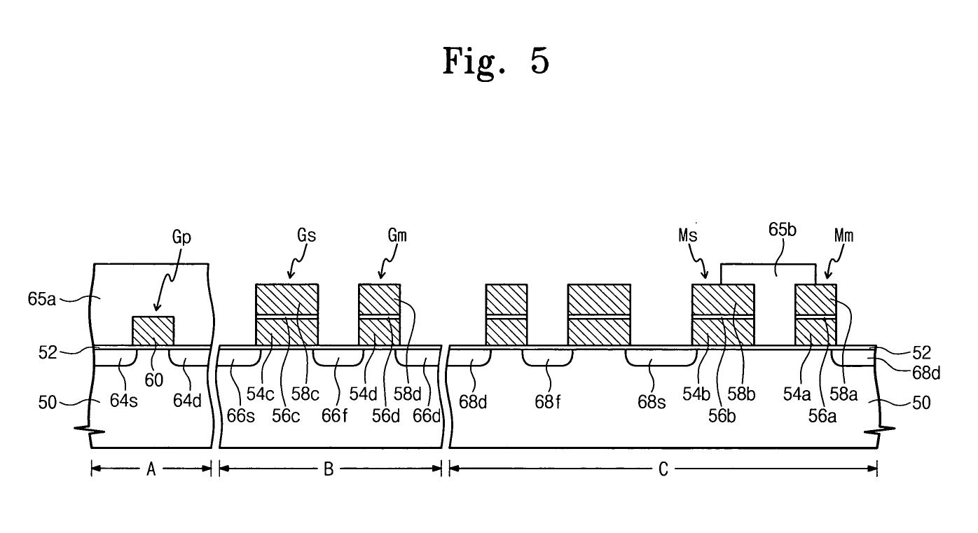

Referring to FIG. 5, the first mask pattern 62 may be removed, and then a second mask pattern 65a and a third mask pattern 65b may be formed on the peripheral circuit region A and a given region of the mask ROM region C. The mask ROM cell may be divided into an on-cell and an off-cell according to coded data. The third mask pattern 65b may cover the active region of the off-cell between the select gate pattern Ms and the memory gate pattern Mm.

Impurity may be implanted in the semiconductor substrate 50 to form a cell source region 66s, a cell diffusion region 66f, and a cell drain region 66d on the EEPROM region B, and to form a source region 68s of the mask ROM cell, a cell diffusion region 68f, and a drain region 68d on the mask ROM region C by using the second mask pattern 65a, the third mask pattern 65b, the exposed select gate pattern Ms, and the memory gate pattern Mm as an ion implantation mask.

After removing the second mask pattern 65a and the third mask pattern 65b, a manufacturing process may proceed for the junction of an LDD structure or DDD structure, and a line forming process may be performed according to typical EEPROM manufacturing processes. For example, since the off-cell of the mask ROM region C may not have a cell diffusion region, a current path may be cut off such that data 0 is recorded.

Since the peripheral transistor, the EEPROM cell transistor, and the mask ROM cell transistor may require different characteristics, the source region 64s and the drain region 64d of the peripheral circuit transistor may be separately formed or may be simultaneously formed.

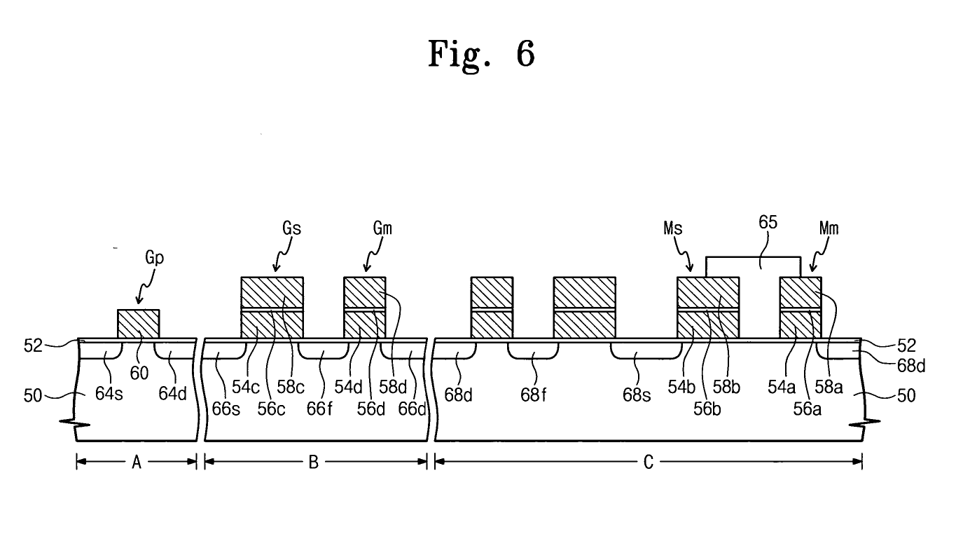

FIGS. 6 through 8 are cross-sectional views illustrating example embodiments of a method of fabricating mask ROM and mask ROM embedded EEPROM.

Referring to FIG. 6, the source region 64s and the drain region 64d of the peripheral circuit transistor may be formed simultaneously on the peripheral circuit region A, the cell source region 66s, the cell diffusion region 66f, and the drain region 66d may be formed simultaneously on the EEPROM region B, and the source region 68s, the cell diffusion region 66f, and the drain region 66d may be formed simultaneously on the mask ROM region C. An ion injection mask 65 may be formed on a region where the off-cell of the mask ROM is formed in order to cover the semiconductor substrate 50 between the select transistor Ms and the memory transistor Mm such that the cell diffusion region is not formed on the off-cell.

The select gate patterns Gs and Ms of the EEPROM cell and the mask ROM cell may have a structure in which the first gate patterns 54c and 54b, the dielectric layers 56c and 56b, and the second gate patterns 58c and 58b are stacked, but may be a single gate pattern structure, for example.

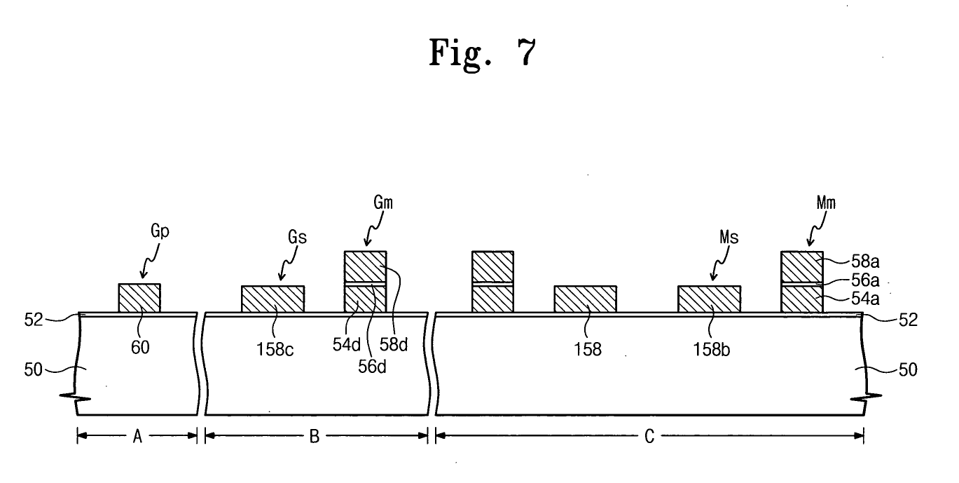

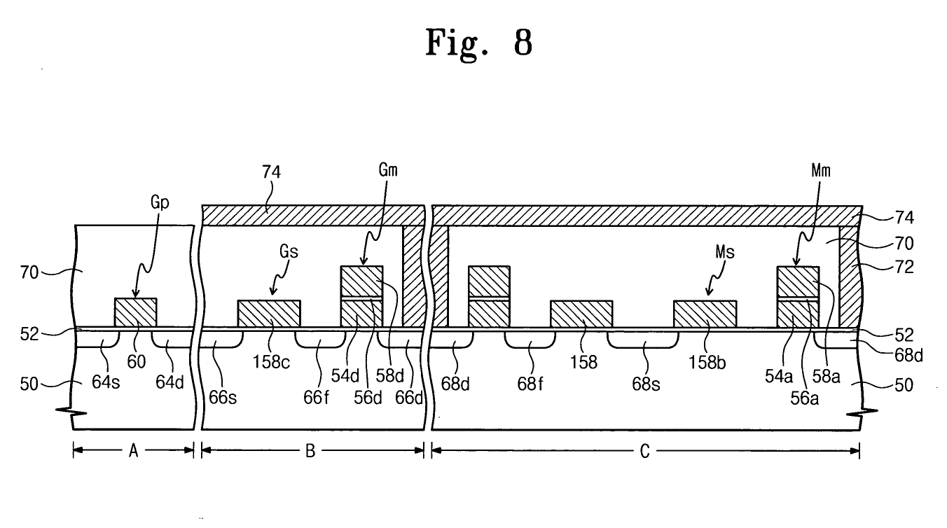

FIGS. 7 and 8 are cross-sectional views illustrating example embodiments of a method of fabricating mask ROM and mask ROM embedded EEPROM.

Referring to FIGS. 7 and 8, select gate patterns Gm and Mm of the EEPROM cell and the mask ROM cell may have a structure including a single gate pattern 158c and 158b. Methods of fabricating the select gate patterns Gm and Mm of a single gate pattern structure are well known, and the select gate patterns Gm and Mm may be formed identical to a floating gate pattern or a control gate pattern. Unlike the stacked structure, a process may not be needed to electrically connect the first gate pattern and the second gate pattern for the select gate patterns Gm and Mm of the single layer.

A mask forming a cell diffusion region by using an ion implantation process may be modified such that a mask ROM cell can be coded into the on-cell and off-cell. A mask used for coding may be unnecessary, thereby reducing manufacturing cost and time.

Since the mask ROM may have a structure similar to that of the EEPROM, an additional drive circuit for a mask ROM operation may not be required, and time for programming mask ROM may not be necessary, thereby reducing manufacturing time.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A mask ROM including an on-cell and an off-cell with a select transistor and a memory transistor, the mask ROM comprising:
a select gate pattern and a memory gate pattern disposed between a source region and a drain region at each of the on-cell and the off-cell,
wherein the on-cell includes a cell diffusion region between the select gate pattern and the memory gate pattern, and the off-cell does not include the cell diffusion region between the select gate pattern and the memory gate pattern.

2. The mask ROM of claim 1, wherein the memory gate pattern includes
a tunnel insulating layer on a semiconductor substrate,
a charge storing layer on the tunnel insulating layer,
a blocking insulation layer on the charge storing layer, and
a control gate electrode on the blocking insulation layer.

3. The mask ROM of claim 1, wherein the select gate pattern includes
a gate insulating layer on a semiconductor substrate, and
a gate electrode on the gate insulating layer.

4. The mask ROM of claim 1, wherein the select gate pattern includes
a gate insulating layer on a semiconductor substrate,
a first gate electrode on the gate insulating layer,
a blocking insulation layer on the first gate electrode, and
a second gate electrode on the blocking insulation layer, wherein the first gate electrode and the second gate electrode are electrically connected.

5. The mask ROM of claim 1, wherein the select transistor and the memory transistor are connected to the cell diffusion region in the on-cell.

6. The mask ROM of claim 1, wherein the select transistor and the memory transistor constitute a 2-transistor memory cell,
select gate patterns of select transistors are connected to a word line, and
memory gate patterns of memory transistors are connected to a sensing line parallel to the word line.

7. The mask ROM of claim 6, further including
a common source line connected to the source regions of the select transistors and disposed parallel to the word line, and
a bit line connected to the drain regions of the memory transistors and intersecting the sensing line and the word line.

8. A mask ROM embedded EEPROM comprising:
an EEPROM cell including a source region, a drain region, a select gate pattern and a memory gate pattern disposed between the source region and the drain region, and a cell diffusion region disposed between the select gate pattern and the memory gate pattern; and
a mask ROM according to claim 1.

9. The mask ROM embedded EEPROM of claim 8, further including a sensing line that connects to at least one of the memory gate pattern and the on-cell memory gate pattern.

10. The mask ROM embedded EEPROM of claim 8, further including a word line that connects to at least one of the select gate pattern and the on-cell select gate pattern.

11. The mask ROM embedded EEPROM of claim 8, further including a bit line that connects to at least one of the drain region and the on-cell drain region.

12. The mask ROM embedded EEPROM of claim 8, wherein the memory gate pattern and the on-cell memory gate pattern include
a tunnel insulating layer on a semiconductor substrate,
a charge storing layer on the tunnel insulating layer,
a blocking insulation layer on the charge storing layer, and
a control gate electrode on the blocking insulation layer.

13. The mask ROM embedded EEPROM of claim 8, wherein the select gate pattern and the on-cell select gate pattern include
a gate insulating layer on a semiconductor substrate, and
a gate electrode on the gate insulating layer.

14. The mask ROM embedded EEPROM of claim 8, wherein the select gate pattern and the on-cell select gate pattern include
a gate insulating layer on a semiconductor substrate,
a first gate electrode on the gate insulating layer,
a blocking insulation layer on the first gate electrode, and
a second gate electrode on the blocking insulation layer, wherein
the first gate electrode and the second gate electrode are electrically connected.

15. A method of fabricating a mask ROM, the method comprising:
providing a semiconductor substrate including an off-cell region and an on-cell region;
forming a select gate pattern and a memory gate pattern on the off-cell region and the on-cell region;
forming a mask pattern to cover the semiconductor substrate between the select gate pattern and the memory gate patterns in the off-cell region; and
forming a source region disposed in the semiconductor substrate adjacent to the select gate pattern, a cell diffusion layer disposed in the semiconductor substrate between the select gate pattern and the memory gate pattern of the on-cell region, and a drain region disposed in the semiconductor substrate adjacent to the memory gate pattern by implanting impurity on the off-cell region and the on-cell region using the mask pattern as an ion implantation mask.

16. The method of claim 15, further including implanting impurity of high concentration on the source region and the drain region.

17. A method of fabricating a mask ROM embedded EEPROM, the method comprising:
providing a semiconductor substrate including an EEPROM region, an off-cell region, and an on-cell region;
forming a select gate pattern and a memory gate pattern on the EEPROM region, the off-cell region, and the on-cell region;
forming a mask pattern to cover the semiconductor substrate between the select gate pattern and the memory gate pattern of the off-cell region; and
forming a source region disposed in the semiconductor substrate adjacent to the select gate pattern, a cell diffusion layer disposed in the semiconductor substrate between the select gate pattern and the memory gate pattern of the EEPROM region and the on-cell region, and a drain region disposed in the semiconductor substrate adjacent to the memory gate pattern by implanting impurity on the EEPROM region, the off-cell region, and the on-cell region using the mask pattern as an ion implantation mask.

18. The method of claim 17, further including
defining a peripheral circuit region on the semiconductor substrate,
forming a gate pattern on the peripheral circuit region, and
implanting impurity into the semiconductor substrate on both sides of the gate pattern in the peripheral circuit region.

19. The method of claim 18, wherein the implanting of the impurity into the peripheral circuit region includes masking the EEPROM region, the on-cell region, and the off-cell region in the semiconductor substrate.

20. The method of claim 18, wherein the implanting of the impurity into the semiconductor substrate of the peripheral circuit region is performed during the implanting of the impurity into the semiconductor substrate of the EEPROM region and the on-cell region.
